(19) United States
(12) Patent Application Publication
(10) Pub. No.: US 2025/0151384 A1
(43) Pub. Date: May 8, 2025

(54) SEMICONDUCTOR DEVICE AND MANUFACTURING METHOD THEREOF

(71) Applicant: UNITED MICROELECTRONICS CORP., Hsin-Chu City (TW)

(72) Inventors: Shuo-Lin Hsu, Tainan City (TW); Hung-Chang Chang, Taichung City (TW); Ta-Kang Lo, Taoyuan City (TW); Tsai-Fu Chen, Hsinchu City (TW)

(73) Assignee: UNITED MICROELECTRONICS CORP., Hsin-Chu City (TW)

(21) Appl. No.: 18/540,852

(22) Filed: Dec. 14, 2023

(30) Foreign Application Priority Data
Nov. 7, 2023 (TW) 112142783

(51) Int. Cl. H01L 27/088; H01L 21/308; H01L 21/8252; H01L 29/66; H01L 29/778

(52) U.S. Cl. CPC H10D 84/84; H01L 21/308; H10D 30/015; H10D 30/475; H10D 84/05

(57) ABSTRACT

A manufacturing method of a semiconductor device includes the following steps. A III-V compound semiconductor layer is formed on a first device region and a second device region of a substrate. A III-V compound barrier layer is formed on the III-V compound semiconductor layer. A lamination structure is formed on the III-V compound barrier layer. The lamination structure includes a p-type doped III-V compound layer and a first mask layer disposed thereon. A patterning process is performed to the lamination structure. A first portion of the lamination structure located above the first device region is patterned by the patterning process. A second portion of the lamination structure located above the second device region is removed by the patterning process. A thickness of the second portion of the lamination structure is greater than a thickness of the first portion of the lamination structure before the patterning process.

### BACKGROUND OF THE INVENTION

### 1. Field of the Invention

The present invention relates to a semiconductor device and a manufacturing method thereof, and more particularly, to a semiconductor device including a III-V compound semiconductor layer and a manufacturing method thereof.

### 2. Description of the Prior Art

Because of the semiconductor characteristics, III-V semiconductor compounds may be applied in many kinds of integrated circuit devices, such as high power field effect transistors, high frequency transistors, or high electron mobility transistors (HEMTs). In the high electron mobility transistor, two semiconductor materials with different band-gaps are combined and heterojunction is formed at the junction between the semiconductor materials as a channel for carriers. In recent years, gallium nitride (GaN) based materials have been applied in the high power and high frequency products because of the properties of wider band-gap and high saturation velocity. Two-dimensional electron gas (2DEG) may be generated by the piezoelectricity property of the GaN-based materials, and the switching velocity may be enhanced because of the higher electron velocity and the higher electron density of the 2DEG. In addition, there are many different structural designs for III-V compound semiconductor transistors corresponding to different products and/or circuits, and III-V compound semiconductor transistors having different structures have to be formed on the same wafer. Therefore, how to integrate the manufacturing processes of III-V compound semiconductor transistors with different structures for improving electrical performance of the III-V compound semiconductor transistors has become a research direction for people in the related fields.

### SUMMARY OF THE INVENTION

A semiconductor device and a manufacturing method thereof are provided in the present invention. A lamination structure including a p-type doped III-V compound layer and a mask layer is formed above a first device region and a second device region, and a thickness of the lamination structure located above the second device region is greater than a thickness of the lamination structure located above the first device region for reducing damage to a III-V compound barrier layer located above the second device region during a patterning process performed to the lamination structure. The electrical performance of the transistor structure subsequently formed may be improved accordingly.

According to an embodiment of the present invention, a manufacturing method of a semiconductor device is provided. The manufacturing method includes the following steps. A substrate is provided, and the substrate has a first device region and a second device region. A III-V compound semiconductor layer is formed on the first device region and the second device region. A III-V compound barrier layer is formed on the III-V compound semiconductor layer, and the III-V compound barrier layer is located above the first device region and the second device region. A lamination structure is formed on the III-V compound barrier layer. A first portion of the lamination structure is located above the first device region, and a second portion of the lamination structure is located above the second device region. The lamination structure includes a p-type doped III-V compound layer and a first mask layer. The p-type doped III-V compound layer is located in the first portion and the second portion of the lamination structure. The first mask layer is disposed on the p-type doped III-V compound layer, and the first mask layer is located in the first portion and the second portion of the lamination structure. Subsequently, a patterning process is performed to the lamination structure. The first portion of the lamination structure is patterned by the patterning process, the second portion of the lamination structure is removed by the patterning process, and a thickness of the second portion of the lamination structure is greater than a thickness of the first portion of the lamination structure before the patterning process.

According to an embodiment of the present invention, a semiconductor device is provided. The semiconductor device includes a substrate, a III-V compound semiconductor layer, a III-V compound barrier layer, and a patterned p-type doped III-V compound layer. The substrate has an enhancement mode device region and a depletion mode device region. The III-V compound semiconductor layer is disposed on the enhancement mode device region and the depletion mode device region. The III-V compound barrier layer is disposed on the III-V compound semiconductor layer, and the III-V compound barrier layer is located above the enhancement mode device region and the depletion mode device region. The patterned p-type doped III-V compound layer is disposed on the III-V compound barrier layer and located above the enhancement mode device region. A thickness of the III-V compound barrier layer located above the enhancement mode device region is substantially equal to a thickness of the III-V compound barrier layer located above the depletion mode device region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 are schematic drawings illustrating a manufacturing method of a semiconductor device according to a first embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, and FIG. 7 is a schematic drawing in a step subsequent to FIG. 6.

FIG. 8 is a schematic drawing illustrating a semiconductor device according to another embodiment of the present invention.

FIGS. 9-12 are schematic drawings illustrating a manufacturing method of a semiconductor device according to a second embodiment of the present invention, wherein FIG. 10 is a schematic drawing in a step subsequent to FIG. 9, FIG. 11 is a schematic drawing in a step subsequent to FIG. 10, and FIG. 12 is a schematic drawing in a step subsequent to FIG. 11.

FIGS. 13-15 are schematic drawings illustrating a manufacturing method of a semiconductor device according to a third embodiment of the present invention, wherein FIG. 14 is a schematic drawing in a step subsequent to FIG. 13, and FIG. 15 is a schematic drawing in a step subsequent to FIG. 14.

FIG. 16 and FIG. 17 are schematic drawings illustrating a manufacturing method of a semiconductor device according to a fourth embodiment of the present invention, wherein FIG. 17 is a schematic drawing in a step subsequent to FIG. 16.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

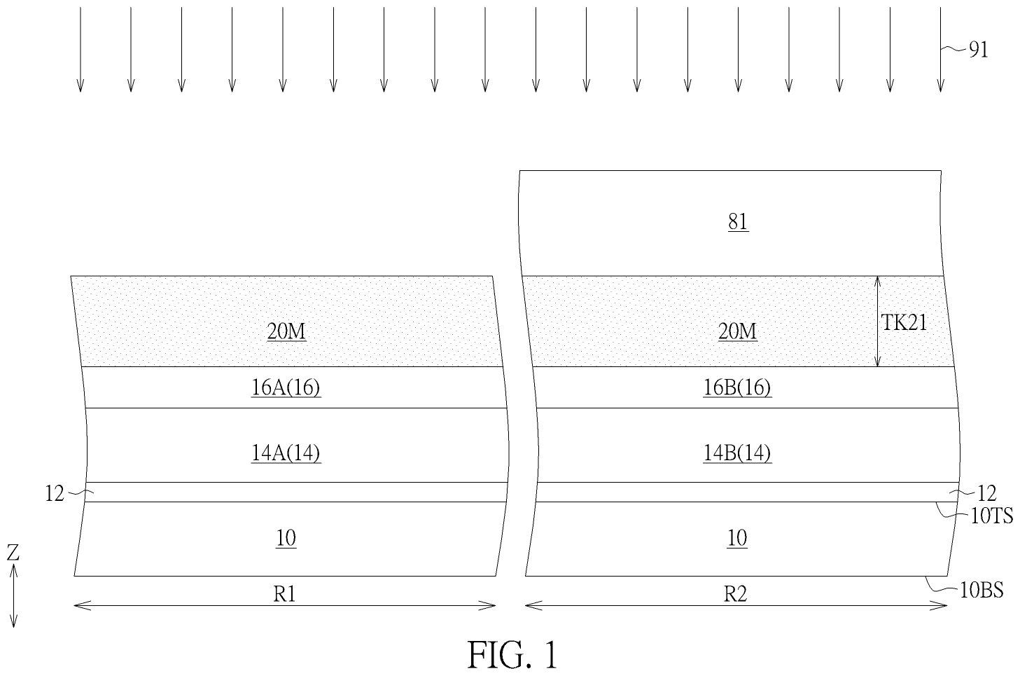

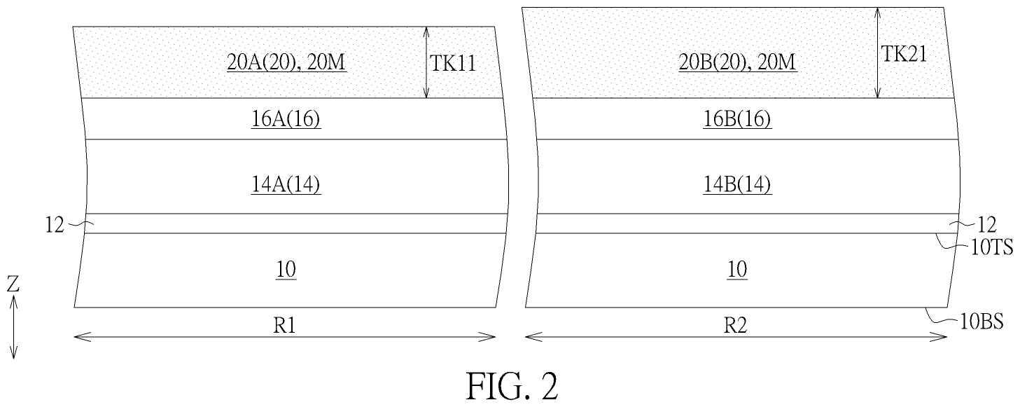

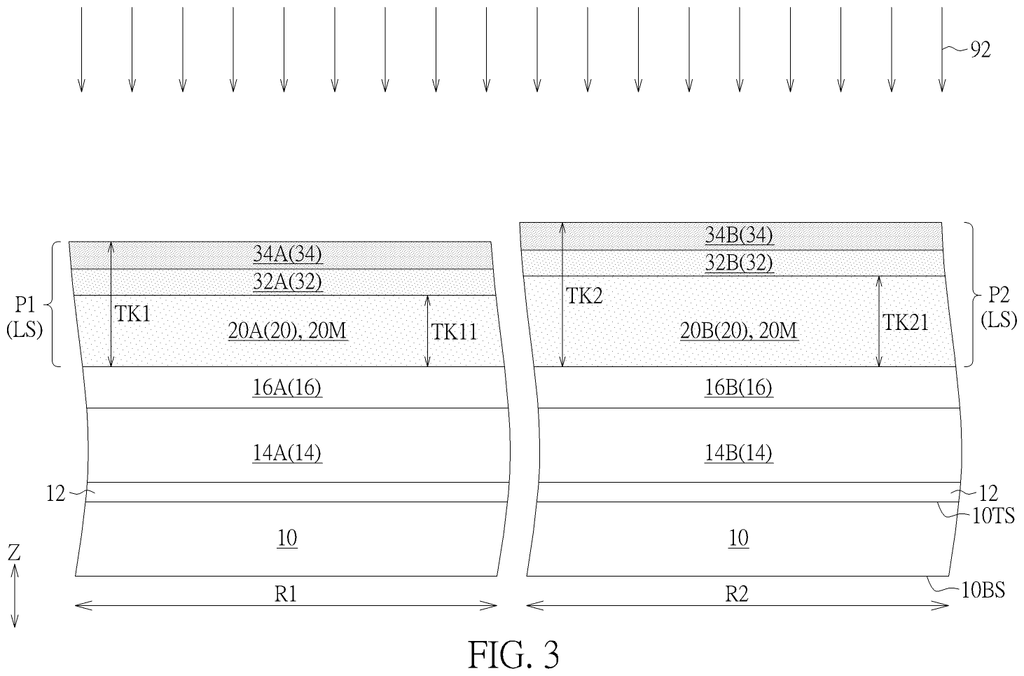

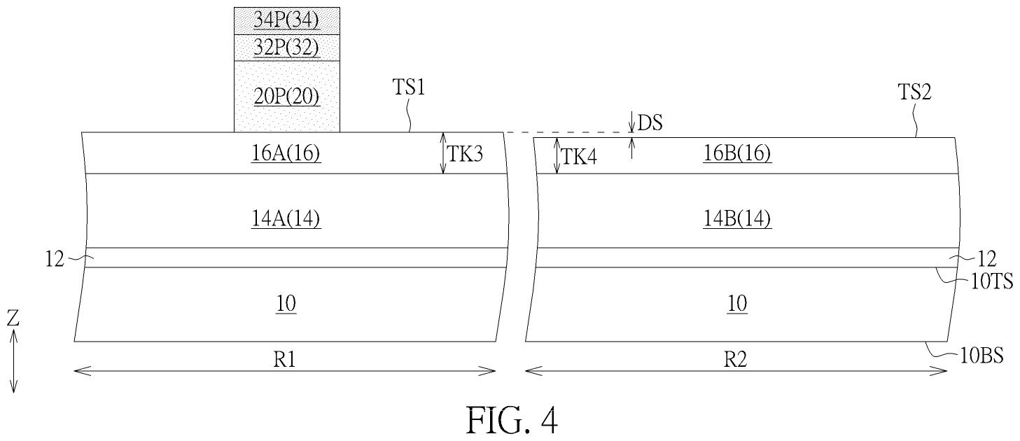

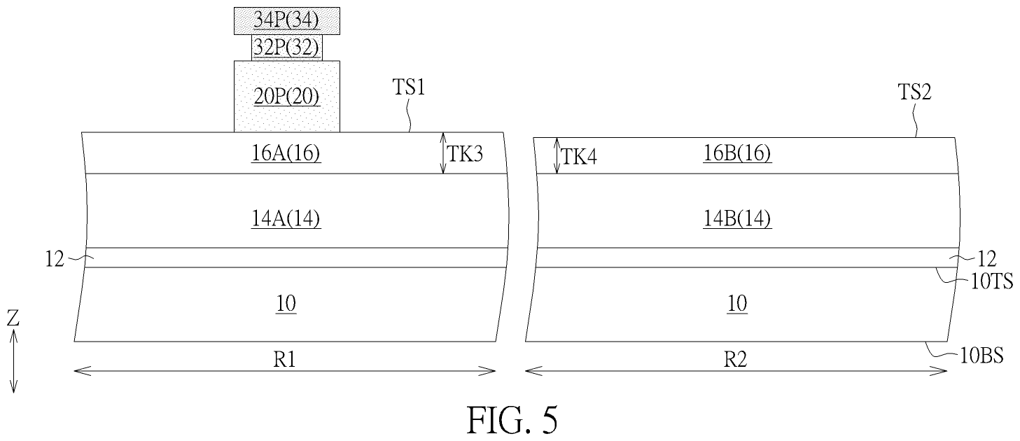

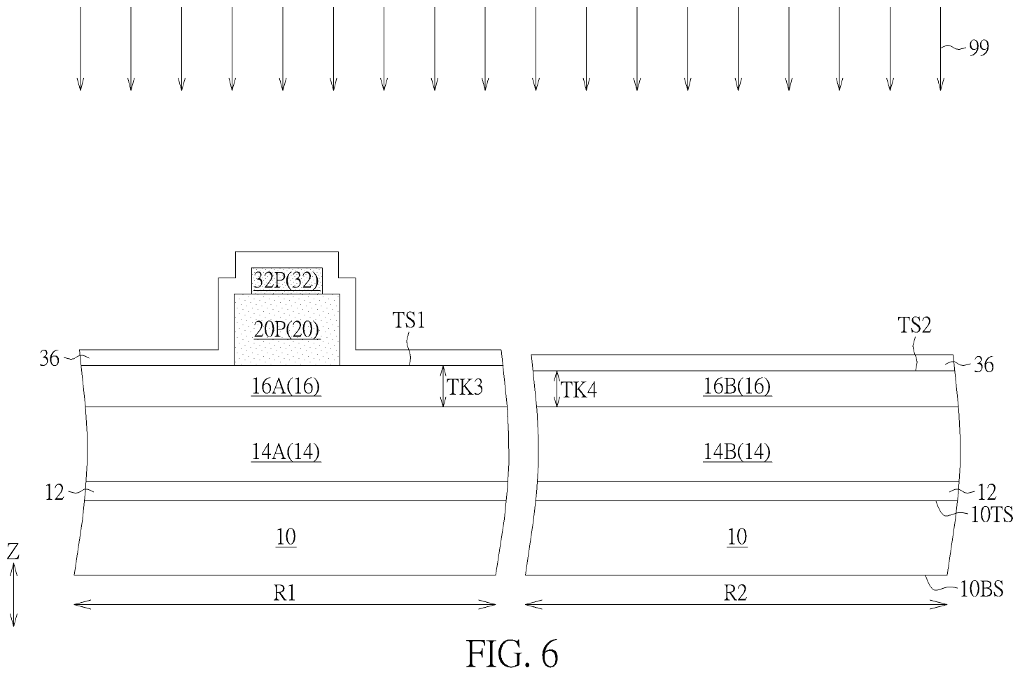

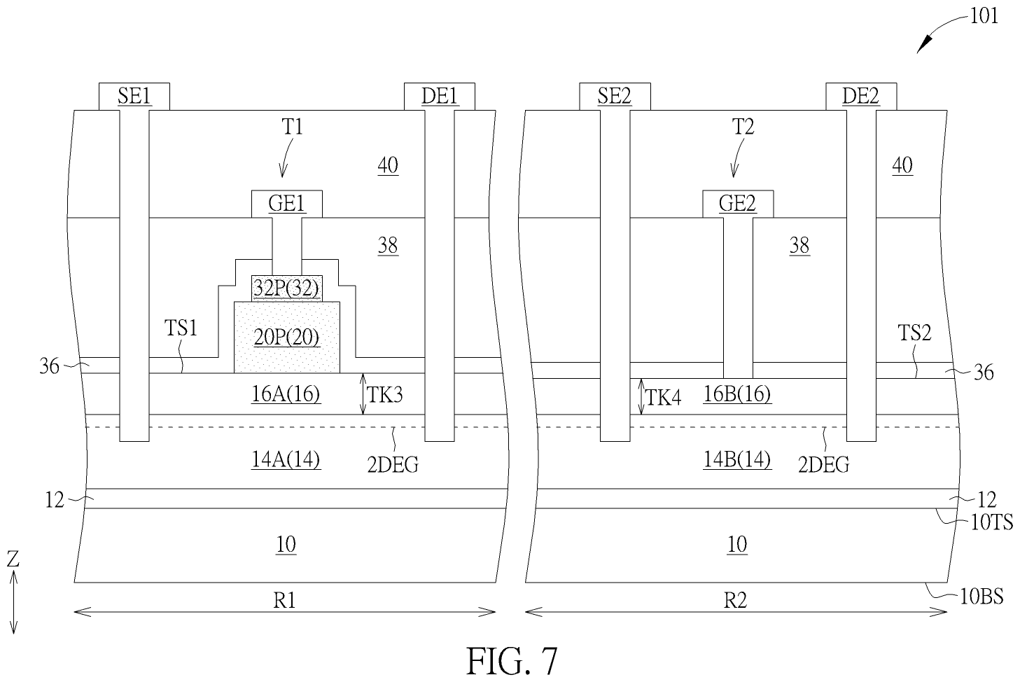

Please refer to FIGS. 1-7. FIGS. 1-7 are schematic drawings illustrating a manufacturing method of a semiconductor device according to a first embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, and FIG. 7 is a schematic drawing in a step subsequent to FIG. 6. The manufacturing method of the semiconductor device is provided in this embodiment and includes the following steps. As shown in FIG. 1, a substrate 10 is provided, and the substrate 10 has a first device region R1 and a second device region R2. Subsequently, a III-V compound semiconductor layer 14 is formed on the first device region R1 and the second device region R2, a III-V compound barrier layer 16 is formed on the III-V compound semiconductor layer 14, and the III-V compound barrier layer 16 is located above the first device region R1 and the second device region R2. As shown in FIG. 3, a lamination structure LS is then formed on the III-V compound barrier layer 16. A first portion P1 of the lamination structure LS is located above the first device region R1, and a second portion P2 of the lamination structure LS is located above the second device region R2. The lamination structure LS includes a p-type doped III-V compound layer 20 and a first mask layer 32. The p-type doped III-V compound layer 20 is located in the first portion P1 and the second portion P2 of the lamination structure LS. The first mask layer 32 is disposed on the p-type doped III-V compound layer 20, and the first mask layer 32 is located in the first portion P1 and the second portion P2 of the lamination structure LS. Subsequently, as shown in FIG. 3 and FIG. 4, a patterning process 92 is performed to the lamination structure LS. The first portion P1 of the lamination structure LS is patterned by the patterning process 92, the second portion P2 of the lamination structure LS is removed by the patterning process 92, and a thickness TK2 of the second portion P2 of the lamination structure LS is greater than a thickness TK1 of the first portion P1 of the lamination structure LS before the patterning process 92. The damage to the III-V compound barrier layer 16 located above the second device region R2 in the patterning process 92 and/or the influence of the patterning process 92 on the thickness variation of the III-V compound barrier layer 16 located above the second device region R2 may be reduced because the thickness TK2 of the second portion P2 of the lamination structure LS is greater than the thickness TK1 of the first portion P1 of the lamination structure LS. The thickness difference and/or the height difference between the III-V compound barrier layer 16 located above the first device region R1 and the III-V compound barrier layer 16 located above the second device region R2 may be reduced, and electrical performance of a semiconductor device subsequently formed above the second device region R2 may be improved.

Specifically, the manufacturing method in this embodiment may include but is not limited to the following contents and/or steps. As shown in FIG. 1, in some embodiments, before the step of forming the III-V compound semiconductor layer 14, a buffer layer 12 may be optionally formed on the substrate 10, and the III-V compound semiconductor layer 14 may then be formed on the buffer layer 12. The substrate 10 may have a top surface 10TS and a bottom surface 10BS opposite to the top surface 10TS in a vertical direction Z, and the buffer layer 12, the III-V compound semiconductor layer 14, and the III-V compound barrier layer 16 may be formed at the side of the top surface 10TS. In some embodiments, the vertical direction Z may be regarded as a thickness direction of the substrate 10, and horizontal directions substantially orthogonal to the vertical direction Z may be substantially parallel with the top surface 10TS and/or the bottom surface 10BS of the substrate 10, but not limited thereto. In this description, a distance between the bottom surface 10BS of the substrate 10 and a relatively higher location and/or a relatively higher part in the vertical direction Z may be greater than a distance between the bottom surface 10BS of the substrate 10 and a relatively lower location and/or a relatively lower part in the vertical direction Z. The bottom or a lower portion of each component may be closer to the bottom surface 10BS of the substrate 10 in the vertical direction Z than the top or upper portion of this component. Another component disposed above a specific component may be regarded as being relatively far from the bottom surface 10BS of the substrate 10 in the vertical direction Z, and another component disposed under a specific component may be regarded as being relatively close to the bottom surface 10BS of the substrate 10 in the vertical direction Z. It is worth noting that, in this description, a top surface of a specific component may include the topmost surface of this component in the vertical direction Z, and a bottom surface of a specific component may include the bottommost surface of this component in the vertical direction Z, but not limited thereto. In this description, the condition that a certain component is disposed between two other components in a specific direction may include a condition that the certain component is sandwiched between the two other components in the specific direction. In addition, in this description, a thickness of a specific component may be regarded as a thickness of this component in the vertical direction Z, unless an addition description is accompanied.

In some embodiments, the substrate 10 may include a silicon substrate, a silicon carbide (SiC) substrate, a gallium nitride (GaN) substrate, a sapphire substrate, or a substrate made of other suitable materials. The buffer layer 12 may include gallium nitride, aluminum gallium nitride (AlGaN), aluminum indium nitride (AlInN), or other suitable buffer materials. The III-V compound semiconductor layer 14 may include gallium nitride, indium gallium nitride (InGaN), aluminum gallium nitride, or other suitable III-V compound semiconductor materials. The III-V compound barrier layer 16 may include aluminum gallium nitride, aluminum indium nitride, aluminum gallium indium nitride (AlGaInN), aluminum nitride (AlN), or other suitable III-V compound barrier materials. The p-type doped III-V compound layer 20 may include p-type doped gallium nitride, p-type doped aluminum gallium nitride, or other suitable p-type doped III-V compound materials. In addition, the p-type dopant in the p-type doped III-V compound layer 20 may include cyclopentadienyl magnesium (Cp₂Mg), magnesium, beryllium (Be), zinc (Zn), a combination of the materials described above, or other suitable p-type dopants. As shown in FIG. 3, in some embodiments, the lamination structure LS may further include a second mask layer 34 disposed on the first mask layer 32. The second mask layer 34 is located in the first portion P1 and the second portion P2 of the lamination structure LS, and a material composition of the second mask layer 34 is different from a material composition of the first mask layer 32. For example, the first mask layer 32 may include electrically conductive barrier materials, such as titanium nitride, and the second mask layer 34 may include dielectric mask materials, such as silicon nitride, but not limited thereto. In addition, a first portion 14A and a second portion 14B of the III-V compound semiconductor layer 14 may be located above the first device region R1 and the second device region R2, respectively. A first portion 16A and a second portion 16B of the III-V compound barrier layer 16 may be located above the first device region R1 and the second device region R2, respectively. A first portion 20A and a second portion 20B of the p-type doped III-V compound layer 20 may be located above the first device region R1 and the second device region R2, respectively. A first portion 32A and a second portion 32B of the first mask layer 32 may be located above the first device region R1 and the second device region R2, respectively. A first portion 34A and a second portion 34B of the second mask layer 34 may be located above the first device region R1 and the second device region R2, respectively.

In this embodiment, the method of forming the lamination structure LS may include but is not limited to the following steps. As shown in FIG. 1, a p-type doped III-V compound material 20M may be formed on the first portion 16A and the second portion 16B of the III-V compound barrier layer 16, and the p-type doped III-V compound material 20M may be located above the first device region R1 and the second device region R2 accordingly. Subsequently, a first thinning process (such as a thinning process 91) may be performed to the p-type doped III-V compound material 20M located above the first device region R1 for reducing the thickness of the p-type doped III-V compound material 20M located above the first device region R1. In some embodiments, a patterned mask layer 81 may be formed and cover the p-type doped III-V compound material 20M located above the second device region R2, the patterned mask layer 81 may be used to protect the p-type doped III-V compound material 20M located above the second device region R2 in the thinning process 91, and the patterned mask layer 81 may include photoresist or other suitable mask materials. In some embodiments, the thinning process 91 may include an etching process (such as an etching back process, but not limited thereto) or other suitable thinning approaches, and the patterned mask layer 81 may be removed after the thinning process 91. Before the thinning process 91, the thickness of the p-type doped III-V compound material 20M located above the first device region R1 may be substantially equal to the thickness of the p-type doped III-V compound material 20M located above the second device region R2 (may be a thickness TK21, for example). As show in FIG. 1 and FIG. 2, after the thinning process 91, a thickness TK11 of the p-type doped III-V compound material 20M located above the first device region R1 is less than the thickness TK21 of the p-type doped III-V compound material 20M located above the second device region R2. After the thinning process 91, the p-type doped III-V compound material 20M remaining on the III-V compound barrier layer 16 may become the p-type doped III-V compound layer 20 of the lamination structure LS. Therefore, the thickness TK11 of the first portion 20A of the p-type doped III-V compound layer 20 may be less the thickness TK21 of the second portion 20B of the p-type doped III-V compound layer 20, the first portion 20A may consist of the p-type doped III-V compound material 20M located above the first device region R1, and the second portion 20B may consist of the p-type doped III-V compound material 20M located above the second device region R2.

As shown in FIGS. 1-3, after the thinning process 91, the first mask layer 32 may be formed on the p-type doped III-V compound layer 20, and the second mask layer 34 may be formed on the first mask layer 32 for forming the first portion P1 and the second portion P2 of the lamination structure LS on the first device region R1 and the second device region R2, respectively. In some embodiments, the lamination structure LS consists of the p-type doped III-V compound layer 20, the first mask layer 32, and the second mask layer 34. The first portion P1 of the lamination structure LS consists of the first portion 20A of the p-type doped III-V compound layer 20, the first portion 32A of the first mask layer 32, and the first portion 34A of the second mask layer 34, and the second portion P2 of the lamination structure LS consists of the second portion 20B of the p-type doped III-V compound layer 20, the second portion 32B of the first mask layer 32, and the second portion 34B of the second mask layer 34, but not limited thereto. The thickness TK11 of the first portion 20A of the p-type doped III-V compound layer 20 is less than the thickness TK21 of the second portion 20B of the p-type doped III-V compound layer 20 by the method described above, and the thickness TK1 of the first portion P1 of the lamination structure LS may be less than the thickness TK2 of the second portion P2 of the lamination structure LS accordingly. In some embodiments, the thickness TK11 described above may be about 80 nanometers, and the thickness TK21 may be adjusted according to the condition of the patterning process 92. Additionally, the method of forming the first portion 20A and the second portion 20B of the p-type doped III-V compound layer 20 with different thicknesses may include but is not limited to the step described above. The p-type doped III-V compound layer 20 having different thicknesses on the first device region R1 and the second device region R2 and the lamination structure LS having different thicknesses on the first device region R1 and the second device region R2 may be formed by other suitable approaches according to some design considerations.

As shown in FIG. 3 and FIG. 4, the p-type doped III-V compound layer 20, the first mask layer 32, and the second mask layer 34 located in the first portion P1 of the lamination structure LS may be patterned to be a patterned p-type doped III-V compound layer 20P, a first mask pattern 32P, and a second mask pattern 34P located above the first device region R1, respectively, by the patterning process 92. The second portion P2 of the lamination structure LS may be completely removed by the patterning process 92 for exposing a top surface TS2 of the III-V compound barrier layer 16 located above the second device region R2 (such as the second portion 16B). In some embodiments, the patterning process 92 may include a photolithography process and an etching process or other suitable patterning approaches. The patterning process 92 may include one or a plurality of etching steps for etching the p-type doped III-V compound layer 20, the first mask layer 32, and the second mask layer 34, respectively. The second portion P2 of the lamination structure LS located above the second device region R2, which has to be completely removed by the patterning process 92, may be relatively thick by the method described above, and the damage (such as etching damage) to the III-V compound barrier layer 16 located above the second device region R2 caused by the patterning process 92 may be reduced accordingly. Under a relatively ideal condition, a thickness TK3 of the first portion 16A of the III-V compound barrier layer 16 may be substantially equal to a thickness TK4 of the second portion 16B of the III-V compound barrier layer 16 after the patterning process 92. For example, the difference between the thickness TK3 and the thickness TK4 may be less than a predetermined value, and the predetermined value may be 1 nanometer, 2 nanometers, or 3 nanometers, but not limited thereto. In some embodiments, the second portion 16B of the III-V compound barrier layer 16 may still be influenced by the patterning process 92 slightly, and the top surface TS2 of the second portion 16B of the III-V compound barrier layer 16 may be slightly lower than a top surface TS1 of the first portion 16A in the vertical direction Z after the patterning process 92 accordingly. For example, a height difference between the top surface TS2 and the top surface TS1 in the vertical direction Z (such as a distance between the top surface TS2 and the top surface TS1 in the vertical direction Z) may be greater than 0 and less than 3 nanometers, and the difference between the thickness TK3 and the thickness TK4 may be greater than 0 and less than 3 nanometers, but not limited thereto.

As shown in FIGS. 3-5, after the patterning process 92, a lateral etching process may be performed to the first mask pattern 32P, and a contact area between the first mask pattern 32P and the patterned p-type doped III-V compound layer 20P in the vertical direction Z may be less than the total area of the top surface of the patterned p-type doped III-V compound layer 20P accordingly for keeping the sidewall of the first mask pattern 32P from being aligned with the sidewall of the patterned p-type doped III-V compound layer 20P. The leakage current path formed along the sidewall of the first mask pattern 32P and the sidewall of the patterned p-type doped III-V compound layer 20P aligned with each other and the influence on the operation performance of the semiconductor device may be avoided accordingly. As shown in FIG. 5 and FIG. 6, after the lateral etching process performed to the first mask pattern 32P, the second mask pattern 34P may be removed, and a dielectric layer 36 may be formed above the first device region R1 and the second device region R2. The dielectric layer 36 may include aluminum oxide or other suitable dielectric materials. The dielectric layer 36 may cover the second portion 16B of the III-V compound barrier layer 16 above the second device region R2, and the dielectric layer 36 may cover the first portion 16A of the III-V compound barrier layer 16, the patterned p-type doped III-V compound layer 20P, and the first mask pattern 32P above the first device region R1. After the step of forming the dielectric layer 36, an anneal process 99 may be performed to the patterned p-type doped III-V compound layer 20P, and the anneal process 99 may be used to activate the dopants (such as magnesium, but not limited thereto) in the patterned p-type doped III-V compound layer 20P. It is worth noting that, in some embodiments, when the anneal process and the activation are performed to the p-type doped III-V compound material before the step of forming the first mask layer 32, a deactivation effect might be generated by the subsequent patterning process (such as the patterning process 92 illustrated in FIG. 3) to the dopants on the p-type doped III-V compound material, and negative influence of the anneal process and the activation performed to the p-type doped III-V compound material located above the second device region R2 on the second portion 16B of the III-V compound barrier layer 16 located under the p-type doped III-V compound material might be generated. For instance, the dopants in the p-type doped III-V compound material may diffuse into the second portion 16B of the III-V compound barrier layer 16, but not limited thereto. Therefore, the anneal process and the activation performed to the p-type doped III-V compound material after the patterning process (i.e. the patterned p-type doped III-V compound layer 20P) may be used to avoid and/or improved the problem described above.

As shown in FIG. 6 and FIG. 7, after the anneal process 99, a dielectric layer 38, a dielectric layer 40, a gate structure GE1, a gate structure GE2, a source structure SE1, a source structure SE2, a drain structure DE1, and a drain structure DE2 may be formed for forming a semiconductor device 101 including a transistor structure T1 located on the first device region R1 and a transistor structure T2 located on the second device region R2. The dielectric layer 38 may be formed on the dielectric layer 36 and located above the first device region R1 and the second device region R2. The dielectric layer 40 may be formed on the dielectric layer 38 and located above the first device region R1 and the second device region R2. The transistor structure T1 may include the first portion 14A of the III-V compound semiconductor layer 14, the first portion 16A of the III-V compound barrier layer 16, the patterned p-type doped III-V compound layer 20P, the first mask pattern 32P, the gate structure GE1, the source structure SE1, and the drain structure DE1. The transistor structure T2 may include the second portion 14B of the III-V compound semiconductor layer 14, the second portion 16B of the III-V compound barrier layer 16, the gate structure GE2, the source structure SE2, and the drain structure DE2. In the transistor structure T1, the gate structure GE1 may be formed on the patterned p-type doped III-V compound layer 20P, the gate structure GE1 may penetrate through the dielectric layer 38 and the dielectric layer 36 in the vertical direction Z and be electrically connected with the patterned p-type doped III-V compound layer 20P via the first mask pattern 32P. The source structure SE1 and the drain structure DE1 may penetrate through the dielectric layer 40, the dielectric layer 38, the dielectric layer 36, and the first portion 16A of the III-V compound barrier layer 16 in the vertical direction Z and may be partly disposed in the first portion 14A of the III-V compound semiconductor layer 14, but not limited thereto. In the transistor structure T2, the gate structure GE2 may penetrate through the dielectric layer 38 and the dielectric layer 36 in the vertical direction Z and be connected with the second portion 16B of the III-V compound barrier layer 16. The source structure SE2 and the drain structure DE2 may penetrate through the dielectric layer 40, the dielectric layer 38, the dielectric layer 36, and the second portion 16B of the III-V compound barrier layer 16 in the vertical direction Z and may be partly disposed in the second portion 14B of the III-V compound semiconductor layer 14, but not limited thereto.

In some embodiments, the dielectric layer 38 and the dielectric layer 40 may include tetraethoxysilane (TEOS) or other suitable dielectric materials, and the gate structure GE1, the gate structure GE2, the source structure SE1, the source structure SE2, the drain structure DE1, and the drain structure DE2 may respectively include a barrier layer (not illustrated) and a metal layer (not illustrated) disposed on the barrier layer, but not limited thereto. The barrier layer described above may include titanium, titanium nitride, tantalum, tantalum nitride, or other suitable electrically conductive barrier materials, and the metal layer described above may include tungsten, copper, aluminum, titanium aluminum alloy, aluminum copper alloy, or other suitable metallic materials. In the transistor structure T1 and the transistor structure T2, two-dimensional electron gas 2DEG may be formed at a position in the III-V compound semiconductor layer 14 and located adjacent to the interface between the III-V compound semiconductor layer 14 and the III-V compound barrier layer 16, the two-dimensional electron gas 2DEG in the transistor structure T1 may be partly located between the source structure SE1 and the drain structure DE1 in the horizontal direction, and the two-dimensional electron gas 2DEG in the transistor structure T2 may be partly located between the source structure SE2 and the drain structure DE2 in the horizontal direction, but not limited thereto. In some embodiments, the transistor structure T1 including the patterned p-type doped III-V compound layer 20P may be regarded as an enhancement mode (E-mode) transistor, and the transistor structure T2 without a p-type doped III-V compound layer may be regarded as a depletion mode (D-mode) transistor. Therefore, the first device region R1 may be an enhancement mode device region, and the second device region R2 may be a depletion mode device region, but not limited thereto. By the manufacturing method described above, the damage to the second portion 16B of the III-V compound barrier layer 16 in the transistor structure T2 during the step of forming the patterned p-type doped III-V compound layer 20P may be reduced, and the electrical performance of the transistor structure T2 may be improved accordingly (such as reducing the leakage current Ioff of the transistor structure T2, but not limited thereto). In addition, the transistor structures formed by the manufacturing method in the present invention are not limited to the transistor structure T1 and the transistor structure T2 illustrated in FIG. 7, and transistors with other structures may also be formed on the first device region R1 and the second device region R2 by the manufacturing method in the present invention.

As shown in FIG. 7, the semiconductor device 101 includes the substrate 10, the III-V compound semiconductor layer 14, the III-V compound barrier layer 16, and the patterned p-type doped III-V compound layer 20P. The substrate 10 has an enhancement mode device region (such as the first device region R1) and a depletion mode device region (such as the second device region R2). The III-V compound semiconductor layer 14 is disposed on the first device region R1 and the second device region R2. The III-V compound barrier layer 16 is disposed on the III-V compound semiconductor layer 14, and the III-V compound barrier layer 16 is located above the first device region R1 and the second device region R2. The patterned p-type doped III-V compound layer 20P is disposed on the III-V compound barrier layer 16 and located above the first device region R1. The thickness TK3 of the III-V compound barrier layer 16 located above the first device region R1 is substantially equal to the thickness TK4 of the III-V compound barrier layer 16 located above the second device region R2. In some embodiments, the difference between the thickness TK3 and the thickness TK4 may be less than a predetermined value, and the predetermined value may be 1 nanometer, 2 nanometers, or 3 nanometers, but not limited thereto. Additionally, in some embodiments, the top surface TS2 of the III-V compound barrier layer 16 located above the second device region R2 may be slightly lower than the top surface TS1 of the III-V compound barrier layer 16 located above the first device region R1 in the vertical direction Z. For example, the distance DS between the top surface TS1 and the top surface TS2 in the vertical direction Z may be greater than 0 and less than 3 nanometers, and the difference between the thickness TK3 and the thickness TK4 may be greater than 0 and less than 3 nanometers, but not limited thereto.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

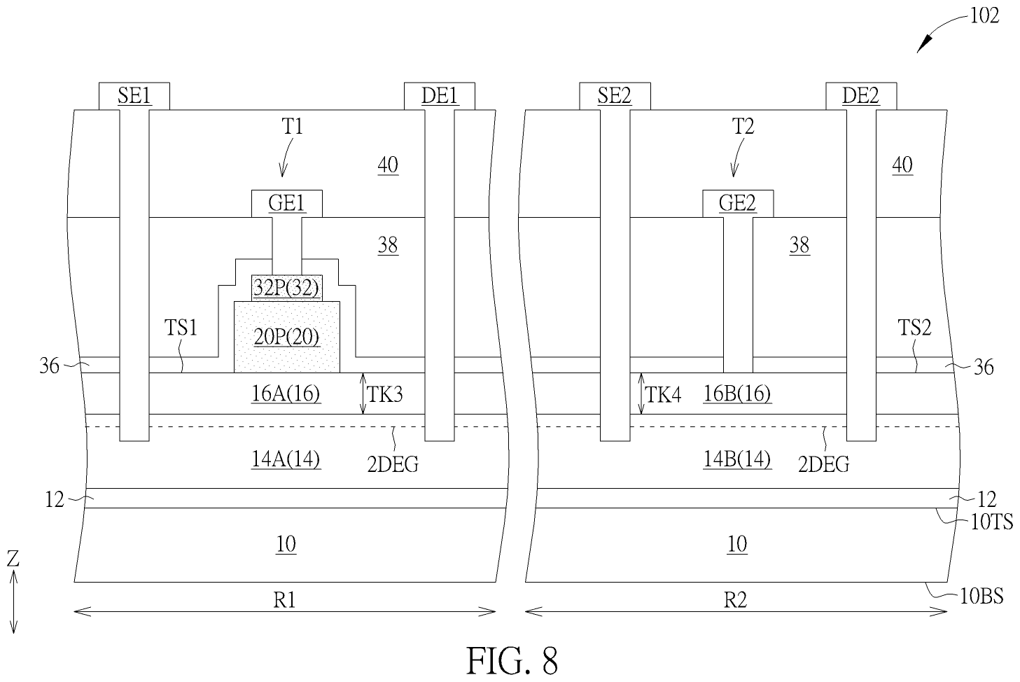

Please refer to FIG. 8. FIG. 8 is a schematic drawing illustrating a semiconductor device 102 according to another embodiment of the present invention. As shown in FIG. 8, in the semiconductor device 102, the thickness TK3 of the III-V compound barrier layer 16 located above the first device region R1 may be substantially equal to the thickness TK4 of the III-V compound barrier layer 16 located above the second device region R2. In some embodiments, the difference between the thickness TK3 and the thickness TK4 may be less than 3 nanometers and substantially equal to zero, and the distance between the top surface TS2 of the III-V compound barrier layer 16 located above the second device region R2 and the top surface TS1 of the III-V compound barrier layer 16 located above the first device region R1 in the vertical direction Z may be less than 3 nanometers and substantially equal to zero, but not limited thereto.

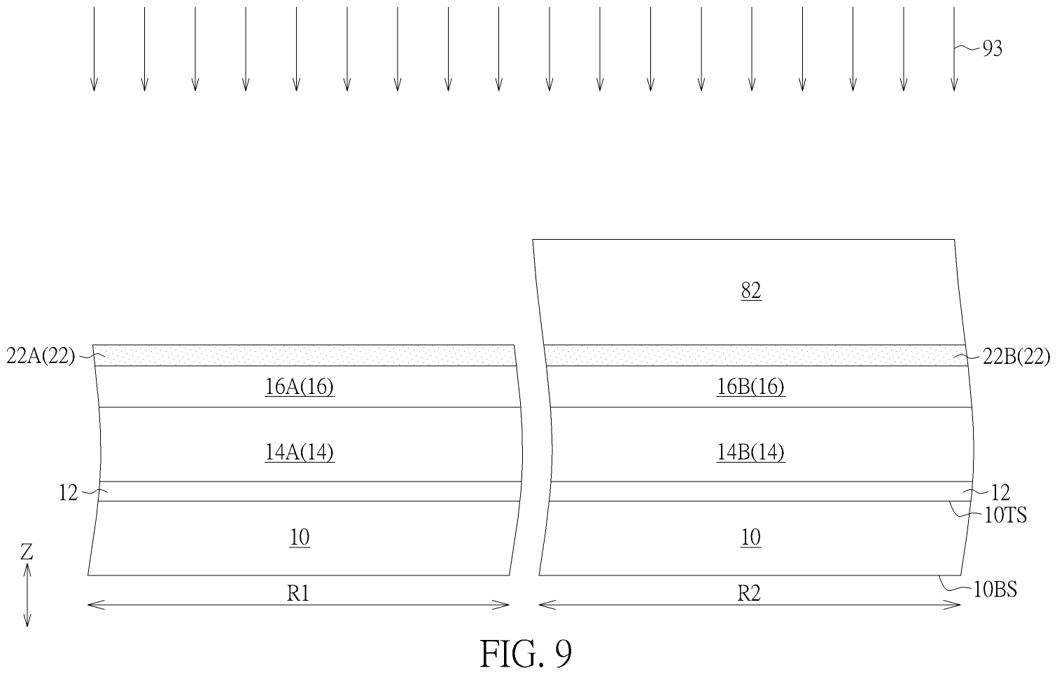

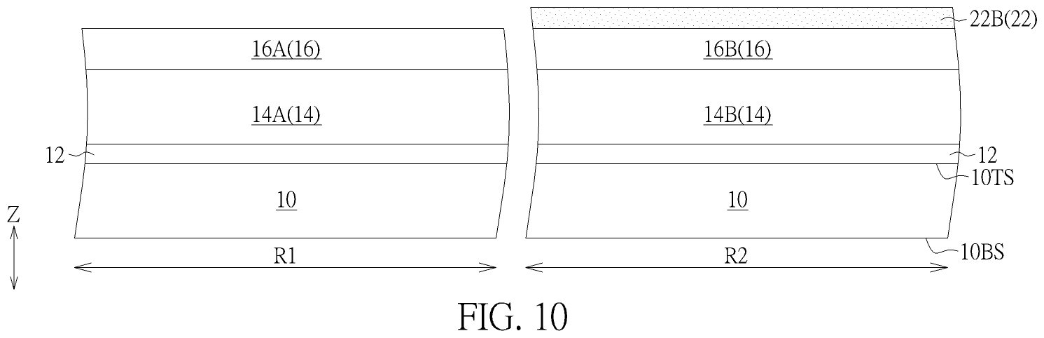

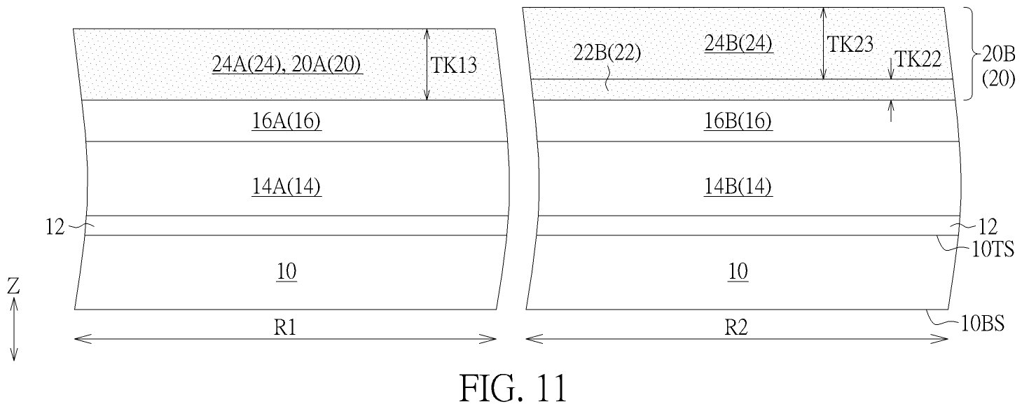

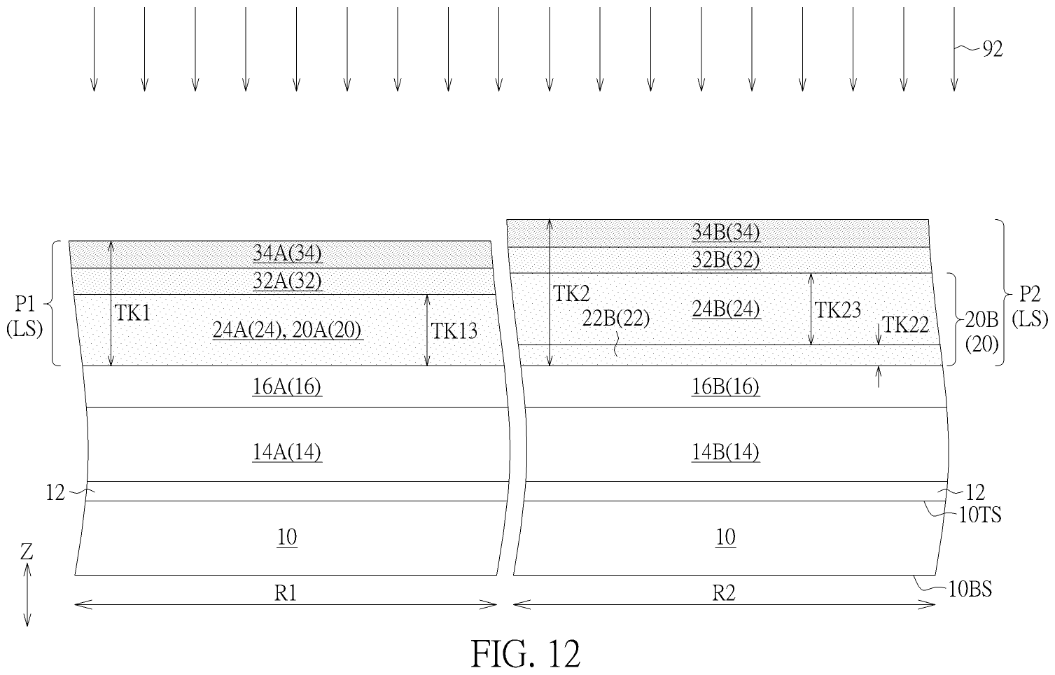

Please refer to FIGS. 9-12 and FIG. 4. FIGS. 9-12 are schematic drawings illustrating a manufacturing method of a semiconductor device according to a second embodiment of the present invention, wherein FIG. 10 is a schematic drawing in a step subsequent to FIG. 9, FIG. 11 is a schematic drawing in a step subsequent to FIG. 10, and FIG. 12 is a schematic drawing in a step subsequent to FIG. 11. In some embodiments, FIG. 4 may be regarded as a schematic drawing in a step subsequent to FIG. 12, but not limited thereto. In this embodiment, the method of forming the lamination structure LS may include the following steps. As shown in FIG. 9, a first p-type doped III-V compound material 22 may be formed on the III-V compound barrier layer 16, and the first p-type doped III-V compound material 22 is located above the first device region R1 and the second device region R2. A first portion 22A of the first p-type doped III-V compound material 22 may be formed on the first portion 16A of the III-V compound barrier layer 16. A second portion 22B of the first p-type doped III-V compound material 22 may be formed on the second portion 16B of the III-V compound barrier layer 16, and the thickness of the first portion 22A may be substantially equal to the thickness of the second portion 22B. Subsequently, as shown in FIG. 9 and FIG. 10, a removing process 93 may be performed for removing the first p-type doped III-V compound material 22 located above the first device region R1 (such as the first portion 22A) and exposing the top surface of the first portion 16A of the III-V compound barrier layer 16.

In some embodiments, a patterned mask layer 82 may be formed covering the first p-type doped III-V compound material 22 located above the second device region R2 (such as the second portion 22B), the patterned mask layer 82 may be used to protect the first p-type doped III-V compound material 22 located above the second device region R2 in the removing process 93, and the patterned mask layer 82 may include photoresist or other suitable mask materials. In some embodiments, the removing process 93 may include an etching process (such as a wet etching process, but not limited thereto) or other suitable removing approaches, and the first p-type doped III-V compound material 22 located above the first device region R1 (such as the first portion 22A) may be removed by the etching process (such as the wet etching process). As shown in FIGS. 9-11, after the first p-type doped III-V compound material 22 located above the first device region R1 is removed, a second p-type doped III-V compound material 24 may be formed, and the second p-type doped III-V compound material 24 may be formed on the III-V compound barrier layer 16 located above the first device region R1 and formed on the first p-type doped III-V compound material 22 located above the second device region R2. A first portion 24A of the second p-type doped III-V compound material 24 may be formed on and directly contact the first portion 16A of the III-V compound barrier layer 16, a second portion 24B of the second p-type doped III-V compound material 24 may be formed on and directly contact the second portion 22B of the first p-type doped III-V compound material 22, and a thickness TK13 of the first portion 24A of the second p-type doped III-V compound material 24 may be substantially equal to a thickness TK23 of the second portion 24B of the second p-type doped III-V compound material 24. As shown in FIG. 11 and FIG. 12, after the step of forming the second p-type doped III-V compound material 24, the first mask layer 32 may be formed on the second p-type doped III-V compound material 24, and the second mask layer 34 may be formed on the first mask layer 32 for forming the first portion P1 and the second portion P2 of the lamination structure LS on the first device region R1 and the second device region R2, respectively.

In some embodiments, the p-type doped III-V compound layer 20 located in the first portion P1 of the lamination structure LS (such as the first portion 20A described above) may consist of the second p-type doped III-V compound material 24 located above the first device region R1 (such as the first portion 24A), and the p-type doped III-V compound layer 20 located in the second portion P2 of the lamination structure LS (such as the second portion 20B described above) may consist of the first p-type doped III-V compound material 22 located above the second device region R2 (such as the second portion 22B) and the second p-type doped III-V compound material 24 located above the second device region R2 (such as the second portion 24B). The thickness of the first portion 20A of the p-type doped III-V compound layer 20 (such as the thickness TK13) may be less than the thickness of the second portion 20B (such as the sum of a thickness TK22 and the thickness TK23) by this approach, and the thickness TK1 of the first portion P1 of the lamination structure LS may be less than the thickness TK2 of the second portion P2 accordingly. In some embodiments, a material composition of the second p-type doped III-V compound material 24 may be identical to a material composition of the first p-type doped III-V compound material 22, but not limited thereto. In addition, the thickness TK23 of the second p-type doped III-V compound material 24 may be greater than the thickness TK22 of the first p-type doped III-V compound material 22 for avoiding the impact of the too thick first p-type doped III-V compound material 22 on the patterning process 92. Subsequently, as shown in FIG. 12 and FIG. 4, the p-type doped III-V compound layer 20, the first mask layer 32, and the second mask layer 34 located in the first portion P1 of the lamination structure LS may be patterned to be the patterned p-type doped III-V compound layer 20P, the first mask pattern 32P, and the second mask pattern 34P located above the first device region R1, respectively, by the patterning process 92, and the second portion P2 of the lamination structure LS may be completely removed by the patterning process 92 for exposing the top surface TS2 of the III-V compound barrier layer 16 located above the second device region R2. In some embodiments, the manufacturing steps illustrated in FIGS. 5-7 may then be carried out for forming the semiconductor device 101, but not limited thereto.

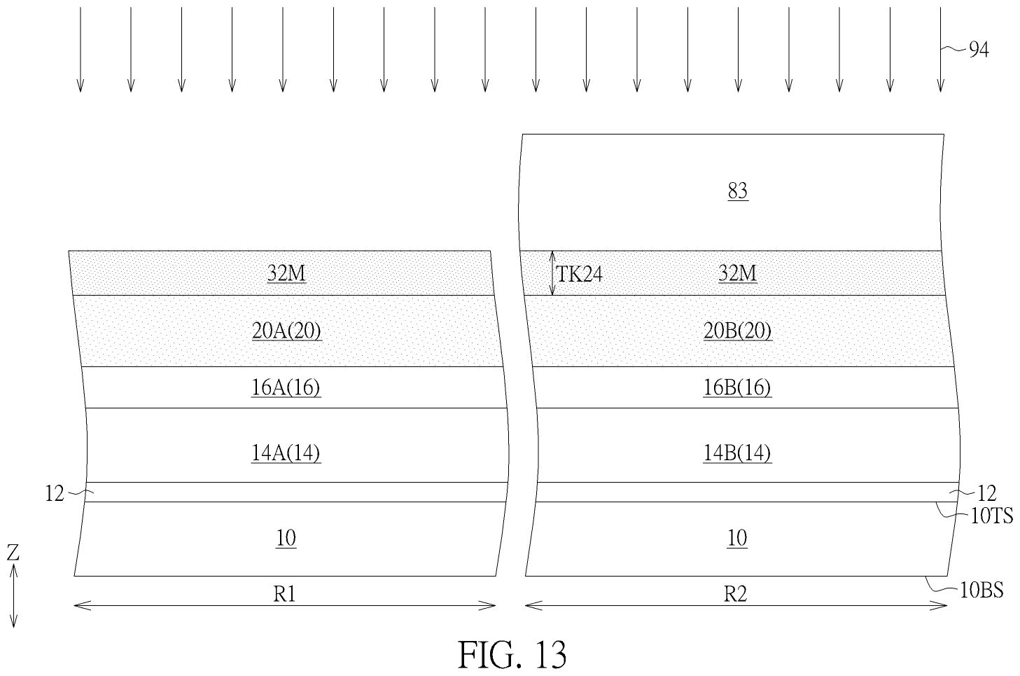

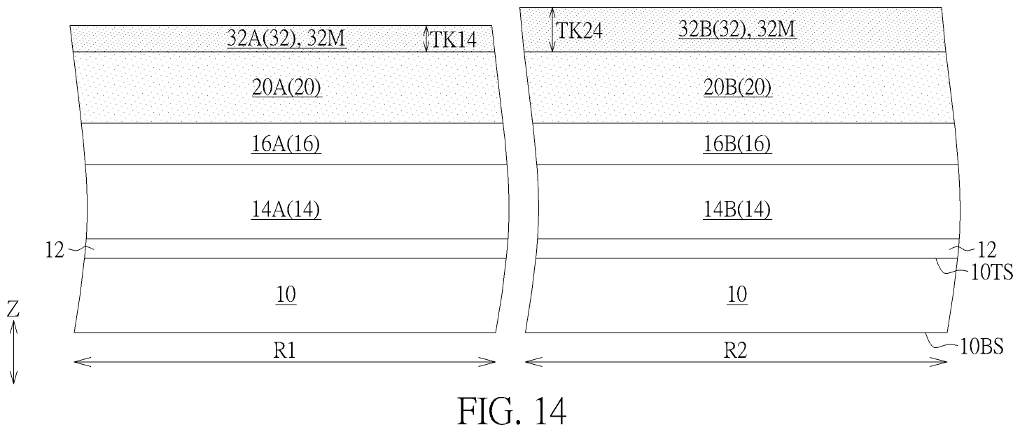

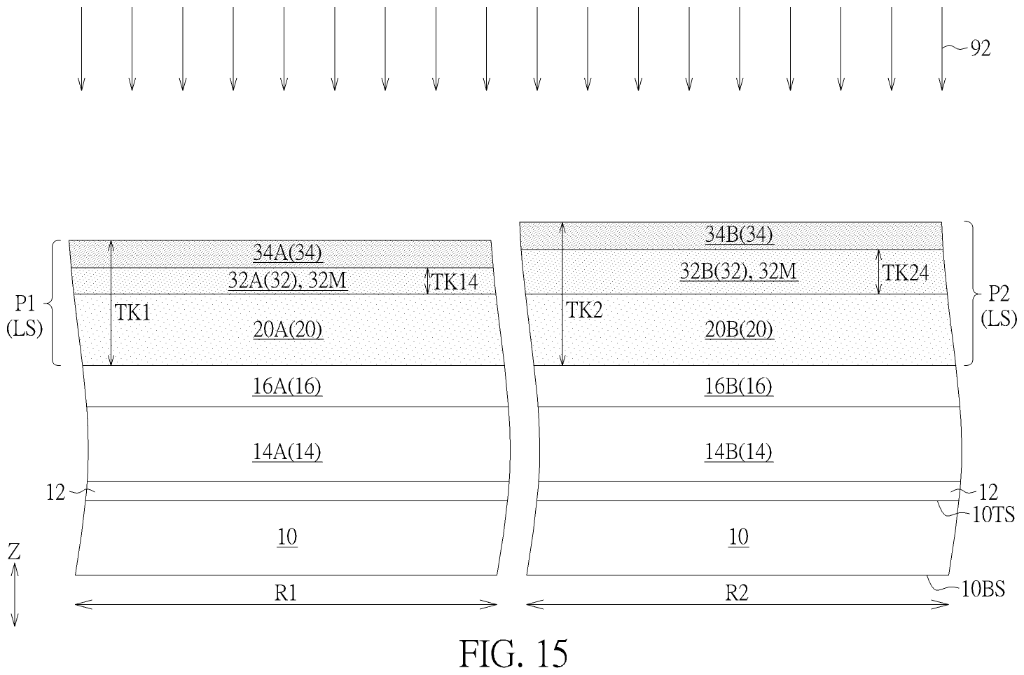

Please refer to FIGS. 13-15 and FIG. 4. FIGS. 13-15 are schematic drawings illustrating a manufacturing method of a semiconductor device according to a third embodiment of the present invention, wherein FIG. 14 is a schematic drawing in a step subsequent to FIG. 13, and FIG. 15 is a schematic drawing in a step subsequent to FIG. 14. In some embodiments, FIG. 4 may be regarded as a schematic drawing in a step subsequent to FIG. 15, but not limited thereto. In this embodiment, the method of forming the lamination structure may include the following steps. As shown in FIG. 13, the p-type doped III-V compound layer 20 may be formed on the III-V compound barrier layer 16, a first mask material 32M may be formed on the p-type doped III-V compound layer 20, and the first mask material 32M is located above the first device region R1 and the second device region R2. A thickness of the first mask material 32M formed on the first portion 20A of the p-type doped III-V compound layer 20 may be substantially equal to a thickness of the first mask material 32M formed on the second portion 20B of the p-type doped III-V compound layer 20. Subsequently, as shown in FIG. 13 and FIG. 14, a second thinning process (such as a thinning process 94) may be performed to the first mask material 32M located above the first device region R1 for reducing the thickness of the first mask material 32M located above the first device region R1. In some embodiments, a patterned mask layer 83 may be formed covering the first mask material 32M located above the second device region R2, the patterned mask layer 83 may be used to protect the first mask material 32M located above the second device region R2 in the thinning process 94, and the patterned mask layer 83 may include photoresist or other suitable mask materials. In some embodiments, the thinning process 94 may include an etching process (such as an etching back process, but not limited thereto) or other suitable thinning approaches, and the patterned mask layer 83 may be removed after the thinning process 94. A thickness TK14 of the first mask material 32M located above the first device region R1 may be less than a thickness TK24 of the first mask material 32M located above the second device region R2 after the thinning process 94. In some embodiments, the thickness TK14 may be about 30 nanometers, and the thickness TK24 may be less than 35 nanometers, but not limited thereto.

As shown in FIGS. 13-15, the first mask material 32M remaining on the p-type doped III-V compound layer 20 after the thinning process 94 may become the first mask layer 32 of the lamination structure LS, and the second mask layer 34 may be formed on the first mask layer 32 after the thinning process 94 for forming the first portion P1 and the second portion P2 of the lamination structure LS on the first device region R1 and the second device region R2, respectively. Therefore, in this embodiment, the thickness TK 14 of the first portion 32A of the first mask layer 32 may be less than the thickness TK24 of the second portion 32B of the first mask layer 32, and the thickness TK1 of the first portion P1 of the lamination structure LS may be less than the thickness TK2 of the second portion P2 accordingly. Subsequently, as shown in FIG. 15 and FIG. 4, the p-type doped III-V compound layer 20, the first mask layer 32, and the second mask layer 34 located in the first portion P1 of the lamination structure LS may be patterned to be the patterned p-type doped III-V compound layer 20P, the first mask pattern 32P, and the second mask pattern 34P located above the first device region R1, respectively, by the patterning process 92, and the second portion P2 of the lamination structure LS may be completely removed by the patterning process 92 for exposing the top surface TS2 of the III-V compound barrier layer 16 located above the second device region R2. In some embodiments, the manufacturing steps illustrated in FIGS. 5-7 may then be carried out for forming the semiconductor device 101, but not limited thereto.

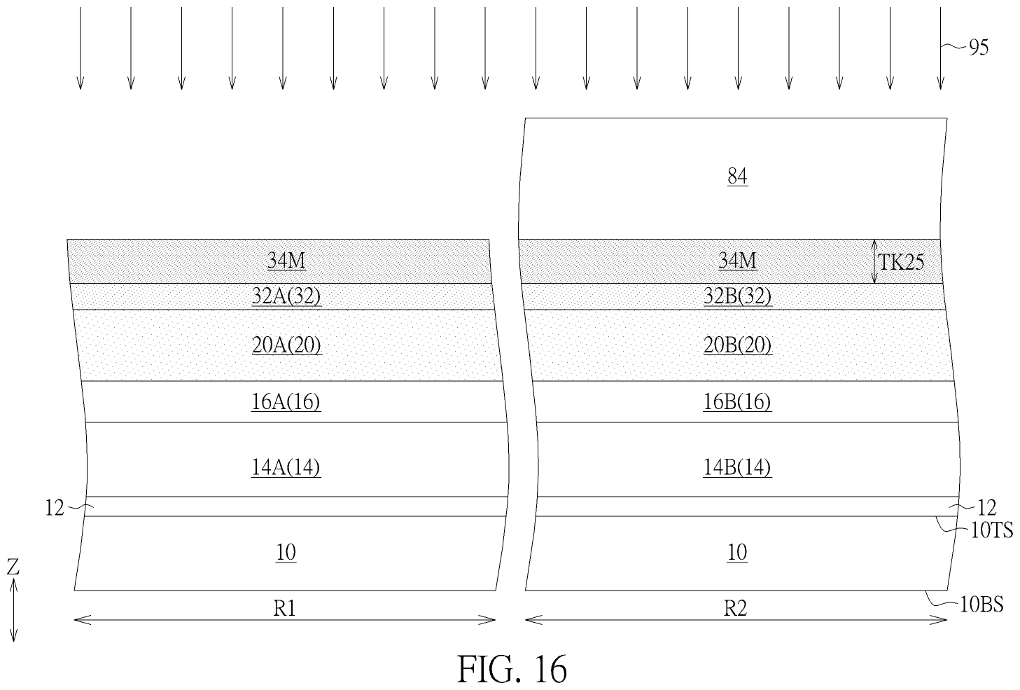

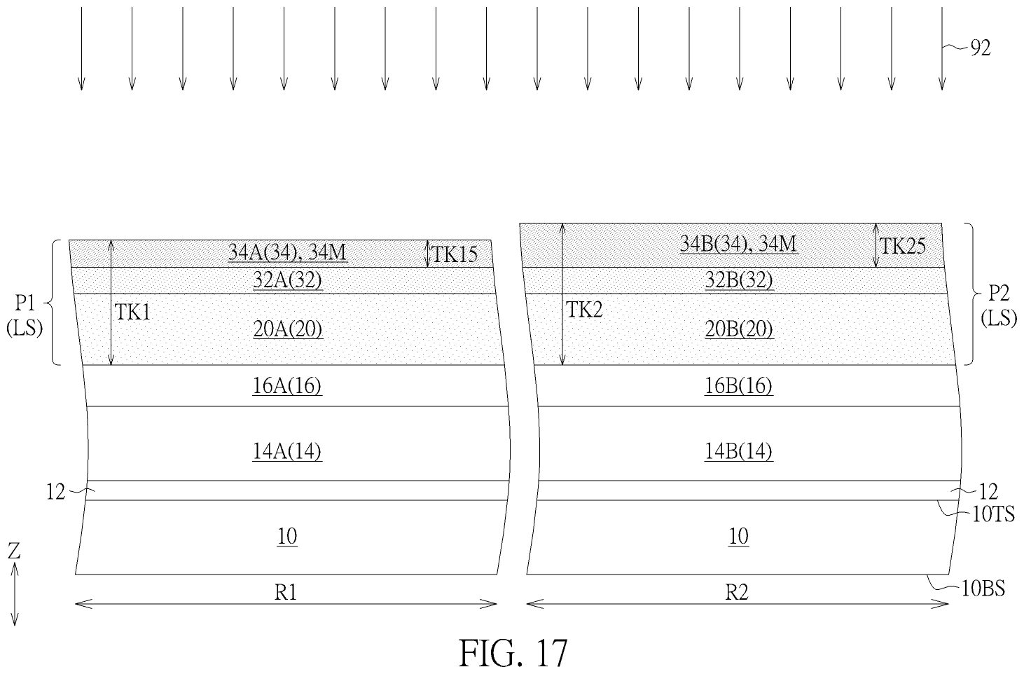

Please refer to FIG. 16, FIG. 17, and FIG. 4. FIG. 16 and FIG. 17 are schematic drawings illustrating a manufacturing method of a semiconductor device according to a fourth embodiment of the present invention, wherein FIG. 17 is a schematic drawing in a step subsequent to FIG. 16. In some embodiments, FIG. 4 may be regarded as a schematic drawing in a step subsequent to FIG. 17, but not limited thereto. In this embodiment, the method of forming the lamination structure may include the following steps. As shown in FIG. 16, the p-type doped III-V compound layer 20 may be formed on the III-V compound barrier layer 16, the first mask layer 32 may be formed on the p-type doped III-V compound layer 20, and a second mask material 34M may be formed on the first mask layer 32. The second mask material 34M is located above the first device region R1 and the second device region R2. A thickness of the second mask material 34M formed on the first portion 32A of the first mask layer 32 may be substantially equal to a thickness of the second mask material 34M formed on the second portion 32B of the first mask layer 32. Subsequently, as shown in FIG. 16 and FIG. 17, a third thinning process (such as a thinning process 95) may be performed to the second mask material 34M located above the first device region R1 for reducing the thickness of the second mask material 34M located above the first device region R1. In some embodiments, a patterned mask layer 84 may be formed covering the second mask material 34M located above the second device region R2, the patterned mask layer 84 may be used to protect the second mask material 34M located above the second device region R2 in the thinning process 95, and the patterned mask layer 84 may include photoresist or other suitable mask materials. In some embodiments, the thinning process 95 may include an etching process (such as an etching back process, but not limited thereto) or other suitable thinning approaches, and the patterned mask layer 84 may be removed after the thinning process 95. A thickness TK15 of the second mask material 34M located above the first device region R1 may be less than a thickness TK25 of the second mask material 34M located above the second device region R2 after the thinning process 95.

The second mask material 34M remaining on the first mask layer 32 after the thinning process 95 may become the second mask layer 34 of the lamination structure LS, and the first portion P1 and the second portion P2 of the lamination structure LS may be formed on the first device region R1 and the second device region R2, respectively, by the thinning process 95 accordingly. In this embodiment, the thickness TK15 of the first portion 34A of the second mask layer 34 may be less than the thickness TK25 of the second portion 34B of the second mask layer 34, and the thickness TK1 of the first portion P1 of the lamination structure LS may be less than the thickness TK2 of the second portion P2 accordingly. Subsequently, as shown in FIG. 17 and FIG. 4, the p-type doped III-V compound layer 20, the first mask layer 32, and the second mask layer 34 located in the first portion P1 of the lamination structure LS may be patterned to be the patterned p-type doped III-V compound layer 20P, the first mask pattern 32P, and the second mask pattern 34P located above the first device region R1, respectively, by the patterning process 92, and the second portion P2 of the lamination structure LS may be completely removed by the patterning process 92 for exposing the top surface TS2 of the III-V compound barrier layer 16 located above the second device region R2. In some embodiments, the manufacturing steps illustrated in FIGS. 5-7 may then be carried out for forming the semiconductor device 101, but not limited thereto.

To summarize the above descriptions, according to the semiconductor device and the manufacturing method thereof in the present invention, the thickness of the lamination structure located above the second device region is greater than the thickness of the lamination structure located above the first device region for reducing the damage to the III-V compound barrier layer located above the second device region in the patterning process and/or the influence of the patterning process on the thickness variation of the III-V compound barrier layer located above the second device region. The electrical performance of the semiconductor device subsequently formed on the second device region may be improved accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a semiconductor device, comprising:
providing a substrate having a first device region and a second device region;
forming a III-V compound semiconductor layer on the first device region and the second device region;
forming a III-V compound barrier layer on the III-V compound semiconductor layer, wherein the III-V compound barrier layer is located above the first device region and the second device region;
forming a lamination structure on the III-V compound barrier layer, wherein a first portion of the lamination structure is located above the first device region, a second portion of the lamination structure is located above the second device region, and the lamination structure comprises:
a p-type doped III-V compound layer located in the first portion and the second portion of the lamination structure; and
a first mask layer disposed on the p-type doped III-V compound layer, wherein the first mask layer is located in the first portion and the second portion of the lamination structure; and
performing a patterning process to the lamination structure, wherein the first portion of the lamination structure is patterned by the patterning process, the second portion of the lamination structure is removed by the patterning process, and a thickness of the second portion of the lamination structure is greater than a thickness of the first portion of the lamination structure before the patterning process.

2. The manufacturing method of the semiconductor device according to claim 1, wherein the second portion of the lamination structure is completely removed by the patterning process for exposing a top surface of the III-V compound barrier layer located above the second device region.

3. The manufacturing method of the semiconductor device according to claim 1, wherein a method of forming the lamination structure comprises:
forming a p-type doped III-V compound material on the III-V compound barrier layer, wherein the p-type doped III-V compound material is located above the first device region and the second device region; and
performing a first thinning process to the p-type doped III-V compound material located above the first device region, wherein a thickness of the p-type doped III-V compound material located above the first device region is less than a thickness of the p-type doped III-V compound material located above the second device region after the first thinning process, and the p-type doped III-V compound material remaining on the III-V compound barrier layer after the first thinning process becomes the p-type doped III-V compound layer of the lamination structure.

4. The manufacturing method of the semiconductor device according to claim 3, wherein the method of forming the lamination structure further comprises:
forming the first mask layer on the p-type doped III-V compound layer after the first thinning process; and
forming a second mask layer on the first mask layer, wherein the second mask layer is located in the first portion and the second portion of the lamination structure, and a material composition of the second mask layer is different from a material composition of the first mask layer.

5. The manufacturing method of the semiconductor device according to claim 1, wherein a method of forming the lamination structure comprises:
forming a first p-type doped III-V compound material on the III-V compound barrier layer, wherein the first p-type doped III-V compound material is located above the first device region and the second device region;
removing the first p-type doped III-V compound material located above the first device region; and
forming a second p-type doped III-V compound material after the first p-type doped III-V compound material located above the first device region is removed, wherein the second p-type doped III-V compound material is formed on the III-V compound barrier layer located above the first device region and formed on the first p-type doped III-V compound material located above the second device region.

6. The manufacturing method of the semiconductor device according to claim 5, wherein the p-type doped III-V compound layer located in the first portion of the lamination structure consists of the second p-type doped III-V compound material located above the first device region, and the p-type doped III-V compound layer located in the second portion of the lamination structure consists of the first p-type doped III-V compound material located above the second device region and the second p-type doped III-V compound material located above the second device region.

7. The manufacturing method of the semiconductor device according to claim 5, wherein a material composition of the second p-type doped III-V compound material is identical to a material composition of the first p-type doped III-V compound material.

8. The manufacturing method of the semiconductor device according to claim 5, wherein a thickness of the second p-type doped III-V compound material is greater than a thickness of the first p-type doped III-V compound material.

9. The manufacturing method of the semiconductor device according to claim 5, wherein the first p-type doped III-V compound material located above the first device region is removed by a wet etching process.

10. The manufacturing method of the semiconductor device according to claim 5, wherein the method of forming the lamination structure further comprises:
forming the first mask layer on the second p-type doped III-V compound material; and
forming a second mask layer on the first mask layer, wherein the second mask layer is located in the first portion and the second portion of the lamination structure, and a material composition of the second mask layer is different from a material composition of the first mask layer.

11. The manufacturing method of the semiconductor device according to claim 1, wherein a method of forming the lamination structure comprises:
forming the p-type doped III-V compound layer on the III-V compound barrier layer;
forming a first mask material on the p-type doped III-V compound layer, wherein the first mask material is located above the first device region and the second device region; and
performing a second thinning process to the first mask material located above the first device region, wherein a thickness of the first mask material located above the first device region is less than a thickness of the first mask material located above the second device region after the second thinning process, and the first mask material remaining on the p-type doped III-V compound layer after the second thinning process becomes the first mask layer of the lamination structure.

12. The manufacturing method of the semiconductor device according to claim 11, wherein the method of forming the lamination structure further comprises:
forming a second mask layer on the first mask layer after the second thinning process, wherein the second mask layer is located in the first portion and the second portion of the lamination structure, and a material composition of the second mask layer is different from a material composition of the first mask layer.

13. The manufacturing method of the semiconductor device according to claim 1, wherein the lamination structure further comprises:
a second mask layer disposed on the first mask layer, wherein the second mask layer is located in the first portion and the second portion of the lamination structure.

14. The manufacturing method of the semiconductor device according to claim 13, wherein the lamination structure consists of the p-type doped III-V compound layer, the first mask layer, and the second mask layer.

15. The manufacturing method of the semiconductor device according to claim 13, wherein a method of forming the lamination structure comprises:
forming the p-type doped III-V compound layer on the III-V compound barrier layer;
forming the first mask layer on the p-type doped III-V compound layer;
forming a second mask material on the first mask layer, wherein the second mask material is located above the first device region and the second device region; and
performing a third thinning process to the second mask material located above the first device region, wherein a thickness of the second mask material located above the first device region is less than a thickness of the second mask material located above the second device region after the third thinning process, and the second mask material remaining on the first mask layer after the third thinning process becomes the second mask layer of the lamination structure.

16. The manufacturing method of the semiconductor device according to claim 1, wherein the p-type doped III-V compound layer in the first portion of the lamination structure is patterned to be a patterned p-type doped III-V compound layer located above the first device region by the patterning process, and the manufacturing method of the semiconductor device further comprises:
forming a gate structure on the patterned p-type doped III-V compound layer; and
performing an anneal process to the patterned p-type doped III-V compound layer after the patterning process and before the gate structure is formed.

17. The manufacturing method of the semiconductor device according to claim 1, wherein the first device region is an enhancement mode device region and the second device region is a depletion mode device region.

18. The manufacturing method of the semiconductor device according to claim 1, wherein a distance between a top surface of the III-V compound barrier layer located above the first device region and a top surface of the III-V compound barrier layer located above the second device region in a vertical direction is less than 3 nanometers.

19. A semiconductor device, comprising:
a substrate having an enhancement mode device region and a depletion mode device region;
a III-V compound semiconductor layer disposed on the enhancement mode device region and the depletion mode device region;
a III-V compound barrier layer disposed on the III-V compound semiconductor layer, wherein the III-V compound barrier layer is located above the enhancement mode device region and the depletion mode device region; and
a patterned p-type doped III-V compound layer disposed on the III-V compound barrier layer and located above the enhancement mode device region, wherein a thickness of the III-V compound barrier layer located above the enhancement mode device region is substantially equal to a thickness of the III-V compound barrier layer located above the depletion mode device region.

20. The semiconductor device according to claim 19, wherein a distance between a top surface of the III-V compound barrier layer located above the enhancement mode device region and a top surface of the III-V compound barrier layer located above the depletion mode device region in a vertical direction is less than 3 nanometers.
